(19) United States
(12) Patent Application Publication
(10) Pub. No.: US 2006/0001051 A1
(43) Pub. Date: Jan. 5, 2006

(54) Thin film semiconductor circuit, manufacturing method thereof, and image display apparatus utilizing the same thin film semiconductor circuit

(76) Inventors: Mitsuharu Tai, Kokubunji (JP); Mutsuko Hatano, Kokubunji (JP); Yoichi Takahara, Tokyo (JP); Hiroki Takahashi, Yokohama (JP); Akio Yazaki, Yokohama (JP); Takeshi Noda, Mobara (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/171,219

(22) Filed: Jul. 1, 2005

(30) Foreign Application Priority Data
Jul. 1, 2004 (JP) 2004-195150

(51) Int. Cl. H01L 29/745; H01L 21/335

(52) U.S. Cl. 257/213; 438/142

(57) ABSTRACT

Agglomeration of a polycrystalline silicon film is eliminated at the time of obtaining a high quality polycrystalline silicon film by forming a silicon layer on an insulating film substrate and conducting long-term melting and re-crystallization. For this purpose, a layer or a plurality of layers of an underlayer UCL are provided on an insulating substrate GLS, the area near the surface in contact with a precursory silicon film PCF provided on this underlayer UCL is formed as an insulating film UCLP showing a film composition to improve the wettability of the melted silicon layer, and thereafter a high quality polycrystalline silicon film PSI is formed through elimination of agglomeration by melting of the precursory silicon film PCF using a laser beam LSR.

### CLAIM OF PRIORITY

The present application claims priority from Japanese application JP 2004-195150 filed on Jul. 1, 2004, the content of which is hereby incorporated by reference into this application.

### FIELD OF THE INVENTION

The present invention relates in general to a thin film semiconductor circuit, a method of manufacture thereof, and an image display apparatus formed of such a thin film semiconductor circuit; and, more particularly, the present invention is suitable for providing a low temperature process polycrystalline silicon thin film transistor which is used to constitute the pixels, a driver circuit and, the other peripheral circuits of a flat type image display apparatus, such as a liquid crystal display device or an organic EL display device.

A thin film transistor (polycrystalline silicon FET) in which the channel thereof is formed of polycrystalline silicon (poly-silicon) has been developed for the pixels and the driver circuit (driver) of such pixels in a flat type image display device or image sensor or the like of an active matrix type liquid crystal display device and organic EL display device. The polycrystalline silicon TFT preferably has a higher driving capability in comparison with a non-crystalline silicon (amorphous silicon) TFT, and this polycrystalline silicon TFT may be mounted, together with the relevant pixels, on an insulator which serves as a substrate (typically, a glass substrate, and hereinafter assumed to be a glass substrate) on which a driver circuit and the other peripheral circuits formed of the polycrystalline silicon TFT are formed around a pixel region. Accordingly, customized circuit specifications are expected to realize a pixel design, a low cost which proceeds simultaneously with the pixel forming process, and a high reliability through avoidance of mechanical fragility of the connecting part between the drive circuit element LSI and the pixels, which remain as problems to be solved in the related art.

For example, the process temperature is specified on the basis of the heat resisting temperature of the glass substrate in the process to form a polycrystalline silicon TFT on the glass substrate for a liquid crystal display device. As a method to form a high quality polycrystalline silicon thin film without subjecting the glass substrate to any thermal damage, a method has been used principally, in which a precursory silicon film is melted using an excimer laser, and it is then re-crystallized. The polycrystalline silicon TFT obtained with this method is improved, by 100 times or more, in its driving capability in comparison with the TFT of the related art in which the channel is formed of amorphous silicon. Therefore, a part of the circuits, such as a driver, may be mounted on the glass substrate.

However, it is necessary to provide a polycrystalline silicon TFT having a higher driving capability in order to mount an LSI having a higher performance. As a method to form the polycrystalline silicon TFT having higher performances, the non-patent document 1 (International Electron Devices Meeting (Washington D.C., 2001) pp747-751) or the non-patent document 2(Society For Information Display International Symposium Digest 2002 pp1580161), for example, proposes a method in which a polycrystalline silicon thin film, having a flat surface, in which the melting time of the relevant silicon layer is expanded and a large grain size and grain width are aligned along the scanning direction of a laser, can be obtained through crystallization of the silicon film by scanning a long-term CW laser, which is longer than that of ELA, or scanning the long-term pulse laser attained by conversion of a CW pulse into a pulse operation with a precisely controlled pulse duration. In addition, it has been reported also that it is possible to improve the polycrystalline silicon TFT by using the polycrystalline silicon thin film, which has been reformed as explained above, as an active layer. Such reformed polycrystalline silicon TFT is provided with a driving capability of two times or more in the N channel in comparison with the polycrystalline silicon TFT of the related art that has been formed using an excimer laser. Accordingly, a larger number of driving circuits and peripheral circuits can be mounted directly on the glass substrate together with the pixels.

Even in the formation of an SOI (Silicon On Insulator), zone-melting and recrystallization are conducted using a heater or a laser in order to obtain a single crystal silicon thin film, as is disclosed in the patent document 1(JP-A 1993-94948). In the case of obtaining a single crystal silicon thin film, a sufficient zone-melting of the silicon film is necessary. However, since thermal damage on the glass substrate is generated when the melting time becomes longer, the method of the patent document 1 cannot realize formation of a single crystal silicon thin film on the glass substrate. Accordingly, the melting time of the silicon film must be set to be longer than that required for crystallization using an excimer laser, but shorter outstandingly in comparison with that of the patent document 1.

### SUMMARY OF THE INVENTION

The crystallization process using a long-term pulse laser is characterized in that the melting time of a precursory silicon film is longer than that when an excimer laser is used, but is sufficiently shorter than that required to form a single crystal silicon thin film. In the case of an excimer laser, the melting time of a precursory silicon thin film is about several tens of nS, while in the case of a long-term pulse laser, it ranges from several hundreds nS to several hundreds μS. In the case of a single crystal, the required melting time is about several mS. The crystal forming time can be extended through elongation of the melting time of the precursory silicon film. Moreover, a high quality polycrystalline silicon film (also referred to as a higher performance polycrystalline silicon film or a reformed polycrystalline silicon film) can also be attained by controlling the crystal growth direction with laser scanning.

Problems which result in the technique of reforming the polycrystalline silicon film, as explained above, are generated on the basis of the characteristics of the crystallization process using a long-term pulse laser, as explained above. In general, the surface tension of the melted silicon is 800 mN/m at a temperature around the melting point, which is sufficiently larger than the surface tension of 490 mN/m of mercury at room temperature. Therefore, the thin film silicon layer under the melted state is stabilized basically in the agglomerated state. When the melting time of a silicon layer is short, as in the case where an excimer laser is used, cooling and coagulation occur before agglomeration, and, therefore, agglomeration is never generated. Meanwhile, in the case of forming a single crystal silicon film, the melting time of the silicon film becomes longer and agglomeration is generated. Accordingly, a certain modification may be required in the formation of the film, as explained in the patent document 1. In the case where a polycrystalline silicon film is formed using a long-term pulse laser, agglomeration is never generated inherently because the melting time is short, as in the case where an excimer laser is used. However, if a structure which will become a trigger, such as fine particle, a non-uniform distribution of film thickness or a non-uniformed laser intensity, exists, agglomeration occurs. Reduction of such a structure, which will become a trigger, may be realized to a certain degree, but such a structure cannot be eliminated perfectly. Therefore, the reduction of agglomeration has a limitation. Actually, when the long-term pulse laser is radiated by 2000 times to a silicon film on the glass substrate, agglomeration is generated about three times.

Since the area where agglomeration is generated includes the region where the silicon layer is peeled off, the operation is impossible even when a TFT is formed to the area where the silicon film is not formed. If agglomeration is generated even at a part of the area where a thin film transistor circuit is formed, the relevant circuit does not operate as a whole, and the yield of a panel is lowered. As a method of solving this problem, it may be thought possible that the scanning rate of laser should be increased and the melting time of silicon film reduced within the range to accelerate crystal growth. However, this method also has a restriction.

Considering such a background, a first object of the present invention is to provide a thin film semiconductor circuit which can include thin film transistors using, as an active layer, a silicon film having a large grain size and a high quality crystal structure by promoting crystal growth through control of agglomeration when a polycrystalline silicon film is formed with laser scanning. A second object of the present invention is to provide a method of manufacturing the thin film semiconductor circuit described above. A third object of the present invention is to provide an image display apparatus which is constituted using the thin film semiconductor circuit described above.

Agglomeration can be controlled by improving the wettability of a silicon film to an insulated substrate and by lowering the influence of surface tension, in addition to reduction in the melting time. For this purpose, the present invention employs a newly proposed means for controlling agglomeration by improving the wettability of the melted silicon to the substrate.

For purposes of achieving the first object, the present invention may be realized by providing an insulated substrate and an underlayer or a plurality of underlayers formed on the insulated substrate, forming an area near the surface in the semiconductor thin film side of the underlayers with a silicon oxide film, and using a semiconductor thin film, in which a plurality of sites among those of oxygen in the silicon oxide film are substituted for an element having an electronegativity smaller than that of oxygen, as an active layer. Here, the silicon oxide film is a film which is characterized, as will be explained in connection with the embodiments, in that the chemical composition ratio of a silicon atom and an oxygen atom is approximately 1:2, and the silicon atom and oxygen atom are bonded with each other with a covalent-bond, while a site is the area where atoms are respectively allocated.

Moreover, as another method, the first object can also be achieved by improving the wettability for an insulated substrate of a silicon film and reducing the influence of the surface tension through fetching of an oxygen atom in the silicon oxide film forming the underlayer into the silicon film.

Moreover, for purposes of achieving the second object, the present invention comprises the steps of forming an insulating film for an underlayer on the insulated substrate, such as a glass substrate, forming a precursory silicon film on the insulating film, forming, to the precursory silicon film, a high quality polycrystalline silicon film having a flat surface in which a large grain size and grain width are aligned in the laser scanning direction by radiating a long-term CW laser or a long-term pulse laser formed by conversion of the CW laser into a pulse operation with a precisely controlled pulse duration, and forming a thin film transistor using this high quality polycrystalline silicon film as an active layer.

For purposes of achieving the third object, the present invention constitutes an image display apparatus using an active matrix substrate with employment of thin film transistors in which the region near the surface in the semiconductor thin film side of the insulated substrate, preferably in the form of a glass substrate, and a layer or a plurality of layers of underlayer formed on the substrate are formed of a silicon oxide film, and the semiconductor thin film, in which an element having a small electronegativity is substituted for a plurality of sites among that of oxygen in the silicon oxide film, is used as the active layer.

Otherwise, an image display apparatus is constituted using an active matrix substrate, including thin film transistors, in which a semiconductor thin film fetching the oxygen atom in the silicon oxide film forming the underlayer into the silicon film serves as the active layer.

According to the present invention, a thin film semiconductor circuit is provided, including thin film transistors, in which agglomeration generated when a high quality crystal is obtained with melting and re-crystallization can be controlled, and also the high quality polycrystalline silicon film can be used as the active layer, and, moreover, a built-in circuit type display apparatus can be obtained with higher manufacturing yield by utilizing such a thin film semiconductor circuit.

### BRIEF DESCRIPTION OF THE DRAWINGS

FIG. 1 is a diagram showing a method of manufacturing a high quality polycrystalline silicon film in accordance with the present invention;

FIG. 2A is a diagrammatic plan view showing the agglomeration generated when an insulating film is used as an ordinary underlayer;

FIG. 2B is a cross-sectional side view taken along line A-B in FIG. 2A, showing the agglomeration generated when the insulating film is used as an ordinary underlayer;

FIG. 3 is diagram illustrating a unit cell of the ideal silicon oxide film;

FIG. 4 is a graph showing the results of analysis, with SIMS, of nitrogen concentration of a silicon oxide film and a SiO film using the TEOS gas as the raw material;

FIG. 5 is a graph showing the results of FTIR of an oxide film;

FIG. 6A and FIG. 6B are diagrams showing a method of arrangement of a thin film transistor;

FIG. 7 is a graph showing comparative transfer characteristics in accordance with a difference in the layout methods of a thin film transistor;

FIG. 8 is a circuit diagram of an image display apparatus representing a third embodiment of the present invention;

FIG. 9 is a developed perspective view showing an example of a structure in which a thin film semiconductor circuit in accordance with the present invention is adapted to a liquid crystal display apparatus;

FIG. 10 is a developed perspective view showing an example of a structure of an organic EL display apparatus representing another example of the image display apparatus of the present invention;

FIG. 11 is a plan view of an organic EL display apparatus in which the structural elements illustrated in FIG. 9 are integrated;

FIG. 12 is a diagram showing an example in which the image display apparatus of the present invention is employed as a monitoring image display apparatus to be used in a personal computer or a TV receiver;

FIG. 13 is a diagram showing an example in which the image display apparatus of the present invention is employed as an image display apparatus of a mobile phone;

FIG. 14 is a diagram showing an example in which the image display apparatus of the present invention is employed as an image display apparatus of a personal digital assistant; and

FIG. 15 is a diagram showing an example in which the image display apparatus of the present invention is employed as an image display apparatus (view finder) of a video camera.

### DETAILED DESCRIPTION OF THE PREFERRED EMBODIMENTS

Various preferred embodiments of the present invention will be explained in more detail with reference to the accompanying drawings.

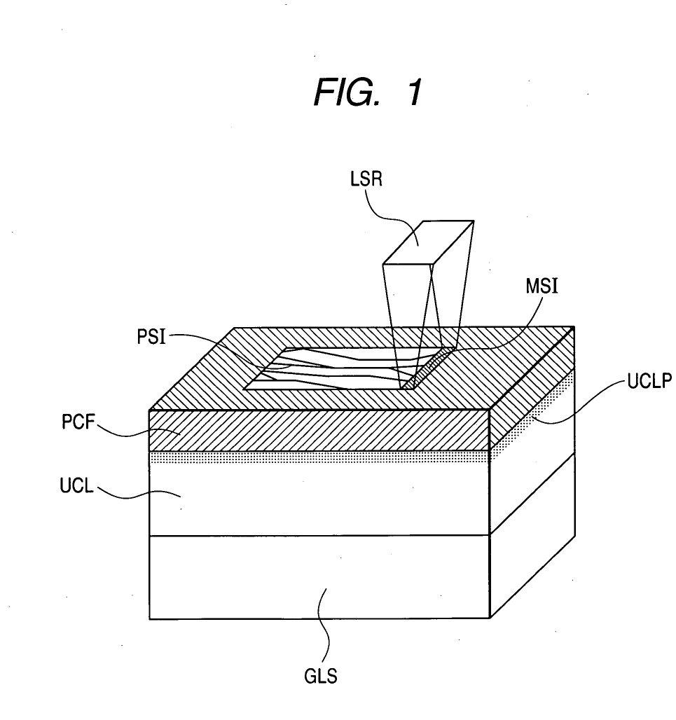

FIG. 1 is a diagram showing a method of manufacturing a high quality polycrystalline silicon film in accordance with the present invention; and, in particular, it shows a method of manufacturing a high quality polycrystalline silicon film PSI on a glass substrate GLS by radiating a laser beam LSR to a silicon film PCF, which is disposed on an insulating film UCL, having improved wettability of the melted silicon layer MSI through alteration of the composition of the film surface UCLP in the side of the silicon film PCF.

That is, the insulating film UCL for use as an under-coat is formed on the glass substrate GLS, and a precursory silicon film PCF is formed thereon. The precursory silicon film may be an amorphous silicon film formed by the CVD (Chemical Vapor Deposition) method, or it may be a polycrystalline film formed by radiating an excimer laser to the entire surface of the amorphous silicon film, or it may be a polycrystalline silicon film formed with another method (for example, a film formed by the CVD method). The high quality polycrystalline silicon film PSI, having a flat surface in which the crystal grain size and grain width are aligned along the laser scanning direction, can be manufactured by radiating a long-term pulse laser beam LSR to the precursory silicon film PCF. The long-term pulse laser beam used here means a laser beam in which the laser beam intensity is converted into a pulse operation with a precisely controlled pulse duration, and the pulse duration is several hundreds of ns or more. This laser beam can be formed with a method using a pulse laser satisfying the conditions, a method used to generate the pulse beam by repeating shielding and transmission of a CW laser beam with a chopper provided in the laser beam path, and a method for generating the pulse beam using an optical modulator, such as an electro-optic modulator.

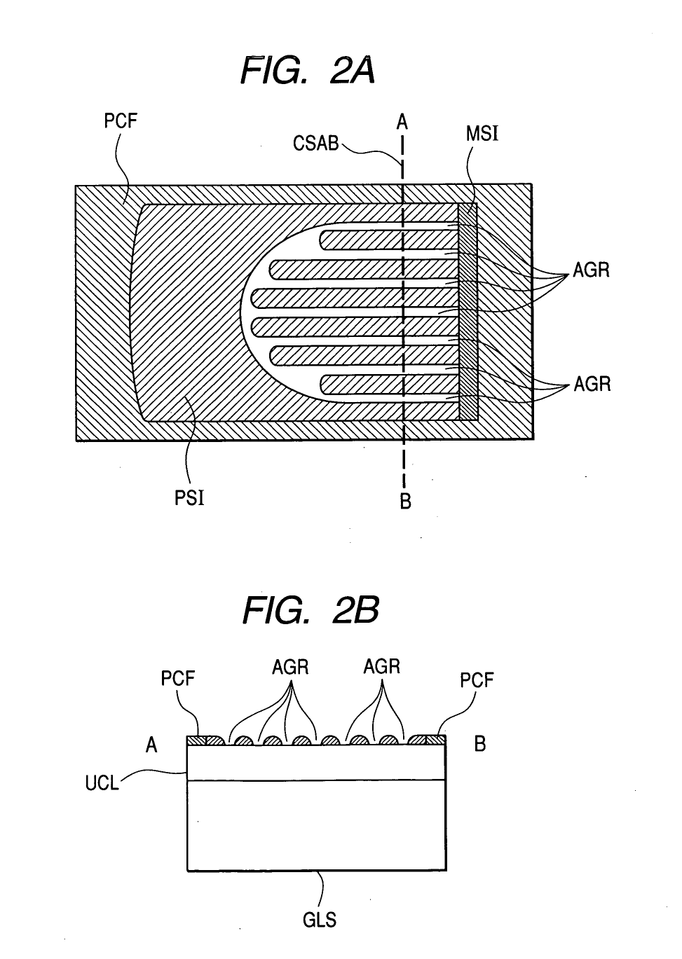

FIGS. 2A and 2B are diagrams showing an example in which the ideal silicon oxide film is used as the underlayer. FIG. 2A is a plan view and FIG. 2B is a sectional view taken along the line A-B in FIG. 2A. Radiation conditions of the long-term pulse laser beam LSR are very important to form the high quality polycrystalline silicon film PSI. The growth rate in the lateral direction for accelerating the crystal growth in the scanning direction is several m/s, and the laser beam width and scanning rate are specified with such a growth rate. When the laser beam width is set to about 10 μm and the scanning rate is set to several hundreds mm/s, the lateral growth can be accelerated. In this case, the laser beam is radiated during the period of hundreds of nanoseconds to hundreds of microseconds, when attention is paid to a certain area within the radiation area, and, therefore, the melting time of the silicon film is assumed to become identical to such period.

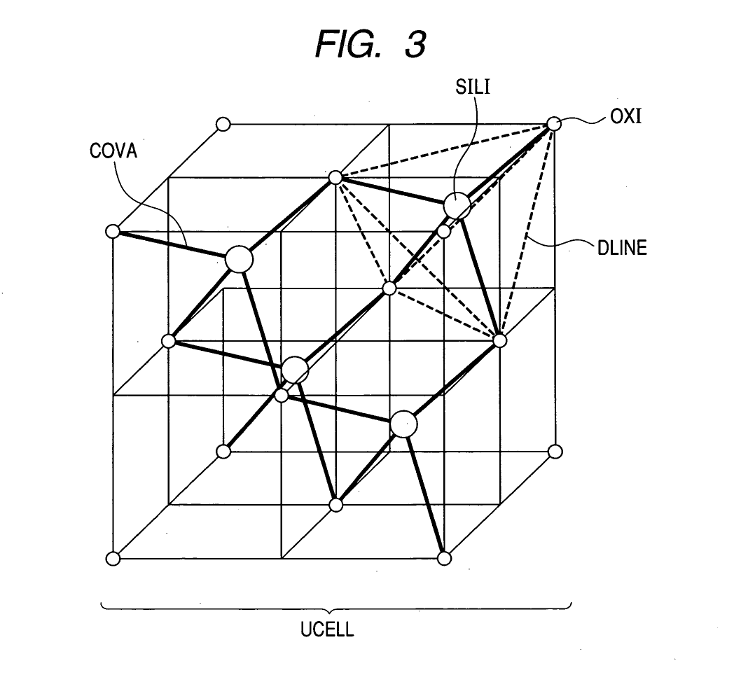

The ideal silicon oxide film used here is a film having the structure as illustrated in FIG. 3, that is, it is constituted by repeating the unit cell UCELL as the basic structure in such a structure wherein the silicon atom SILI is arranged at the center of gravity of the regular tetrahedron, indicated with a broken line DLINE, while the oxygen atom OXI is arranged at the crest of this regular tetrahedron. The silicon atom SILI and the oxygen atom OXI are bonded with each other with the covalent bond COVA. In this case, the chemical composition ratios of the silicon atom SILI and the oxygen atom OXI are respectively 66.67% and 33.33% in the silicon oxide film.

The actual silicon oxide film is different from the ideal film in the arrangement of atoms. Usually, the silicon oxide film is not formed under ideal conditions, with the result that each atom of the unit cell UCEL does not exist at the area where it should exist, locations are displaced, or some covalent bonds are formed. However, the silicon atoms SILI are almost formed in the structure having three to five covalent bonds in average with the oxygen atom OXI from a local viewpoint. If the chemical composition ratio of the oxygen atom OXI is more them 60%, agglomeration appears in the case of the actual silicon oxide film.

In accordance with the present invention, in order to improve the wettability of the melted silicon MSI to the insulating film UCL serving as the underlayer, the chemical composition of the region UCLP near the interface with the silicon film PCF of the insulating film UCL has been modified as follows. In general, the wettability of the melted silicon for a contact layer may be improved as the polarizability of the contact is reduced. The present invention is characterized in that a film or a region having a smaller polarizability is formed to the surface layer of the silicon oxide film UCLP for the silicon oxide film having the chemical composition ratio of the oxygen atom OXI of 60% or more. The present invention will be explained on the basis of the embodiments thereof.

First Embodiment

In the first embodiment, another element is substituted for the oxygen of the silicon oxide film. In this case, the polarization coefficient may be lowered when an element having an electronegativity which is smaller than that of the oxygen element, namely the element belonging to the group smaller than the 6A group, is substituted. Usually, the CVD film formed using TEOS (Tetraethoxysilane) gas as the raw material is employed as the silicon oxide film because it has excellent coverage.

An example of forming a TEOS film will be explained below. First, oxygen gas, helium gas, and TEOS gas are introduced into a chamber in which a substrate is prepared in the flow ratio of 1:1:1. After the gases are stabilized, plasma is generated with the RF output of 450 W in order to form an oxide film on the substrate using the chemical vapor deposition method. When the film is grown up to a thickness of 100 nm under a time control (7 seconds or more), the reaction is stopped.

When a CVD film (hereinafter, called the SiO film) using the mixed gas of N₂O and SiH₄ as the raw material is employed as an alternative, since nitrogen is included in the raw material, the nitrogen concentration in the film increases.

An example of forming the SiO film will be explained below. The N₂O, SiH₄, and Ar gases are introduced into the chamber in which a substrate is prepared with a flow rate of 10:6:11. After the gases are stabilized, plasma is generated with an RF output of 1700 W in order to form an oxide film on the substrate using the chemical vapor deposition method. After the film is grown up to a thickness of 100 nm under a time control (6 seconds or more), the reaction is stopped.

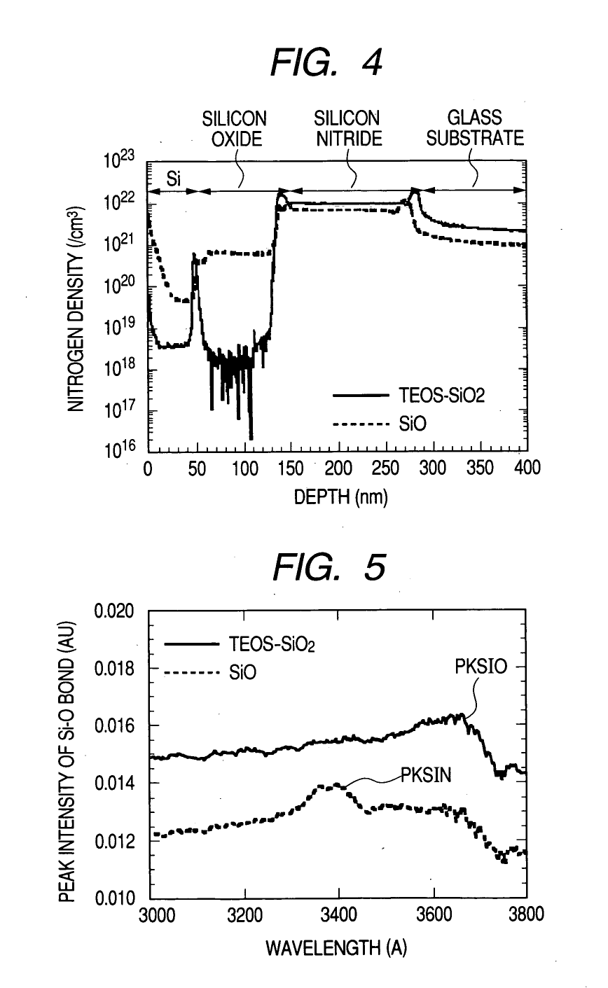

FIG. 4 is a graph showing a result obtained by analyzing the nitrogen concentration in the TEOS film and SiO film with the SIMS (Secondary Ion Mass Spectroscopy) method. In the case of the TEOS film, the nitrogen content is less than the limit of measurement, but the SiO film has a volume density of 5×10²⁰ cm⁻³ or more. In addition, it is proved from the result of XPS that the nitrogen concentration is 2% or more in terms of the chemical composition ratio. The reason for this is that nitrogen included in the raw material gas is substituted at the location (hereinafter called a site) of oxygen in the silicon oxide film.

FIG. 5 is a graph showing the results of FTIR (Fourier Transformation Infra Red spectrometer) analysis of respective oxide films. In the case of a SiO film, the peak PKSIN of the Si—N bond is found in addition to the peak PKSIO of the Si—O bond, and, therefore, it may be understood that nitrogen is substituted at the site of oxygen. When the SiO film is used as the insulating film for the underlayer, it has been confirmed that the generation frequency of agglomeration illustrated in FIGS. 2A and 2B may be controlled.

It is sufficient when the nitrogen concentration in the underlayer UCL becomes high at the region UCLP near the interface to the silicon film, and such nitrogen concentration is not required to be uniform in the entire part of the film UCL. For example, even in the silicon oxide film in which TEOS gas is used as the raw material, the nitrogen concentration of the area UCLP near the interface can be increased and agglomeration can be suppressed by conducting the nitrogen plasma process immediately after formation of the film.

In the method of forming a semiconductor circuit by forming a thin film transistor in which the polycrystalline silicon PSI is used as the active layer, it is sufficient when the method to repeatedly conduct the well known oxidation, film forming process and the photolithography process is employed.

According to the first embodiment, the agglomeration which is generated to obtain a high quality crystal with melting and re-crystallization can be suppressed, and, thereby, the thin film semiconductor circuit including a thin film transistor in which a high quality polycrystalline silicon film is used as the active layer can be attained.

Second Embodiment

Moreover, as a second embodiment, a film other than the silicon oxide, film which can improve wettability of the melted silicon, may be employed for the underlayer UCL. For example, it is recommended to employ silicon carbide (SiC) and diamond-like carbon (DLC) as the underlayer. Any method can be selected from the ion beam evaporation, sputtering, arc discharge and CVD methods for formation of SiC and DLC. DLC may also be formed as a semiconductor material depending on the film forming conditions. When the resistance value is lowered, a disadvantage occurs in that the element-to-element insulation becomes bad and a parasitic element, such as a thyristor, operates. However, as disclosed in the non-patent document 3 (Thin Solid Films 373 2000 pp251-254), the necessary insulation property can be acquired by lowering the film forming temperature and the RF output in regard to the resistivity of DLC.

For the method of manufacturing a semiconductor circuit by forming a thin film transistor using polycrystalline silicon PSI as the active layer, it is sufficient to employ a method for repeatedly conducting the well known oxidation process, film forming process, and photolithography process.

Also, according to the second embodiment, it is possible to obtain a thin film semiconductor circuit including thin film transistors which can control that is agglomeration generated when high quality crystal can be attained through melting and re-crystallization and use the high quality polycrystalline silicon film as the active layer.

Third Embodiment

Unlike the ideal silicon oxide film, the actual silicon oxide film includes OH group and H₂Omolecules in the film. These molecules are in the state captured with a hydrogen bond and a weak bond like an intermolecular force, and the amount of these molecules is determined depending on the film forming method and raw material gas or the like. When the SiO film is employed as the underlayer UCL, the amount of OH group and H₂O molecules captured are considered to be larger than that of the TEOS film. With implementation of a high-temperature heat treatment, such as annealing in a furnace or annealing by excimer laser, an oxygen atom resulting from an OH group and H₂O in the SiO film can be introduced into the silicon film PCF. Moreover, a similar effect can also be attained at the time of melting and re-crystallization using the laser beam LSR. As a result, the wettability of the melted silicon film MSI for the silicon oxide film can be improved, and agglomeration during the re-crystallization can also be controlled.

As a method of forming a semiconductor circuit by forming a thin film transistor using this polycrystalline silicon PSI as the active layer, it is sufficient to employ a method in which the well known oxidation process, film forming process and photolithography process are repeated.

According to the third embodiment, it is also possible to control agglomeration which is generated when a high quality crystal is obtained with the melting and re-crystallization processes, and, thereby to obtain a thin film semiconductor circuit including a thin film transistor using the high quality polycrystalline silicon film as an active film.

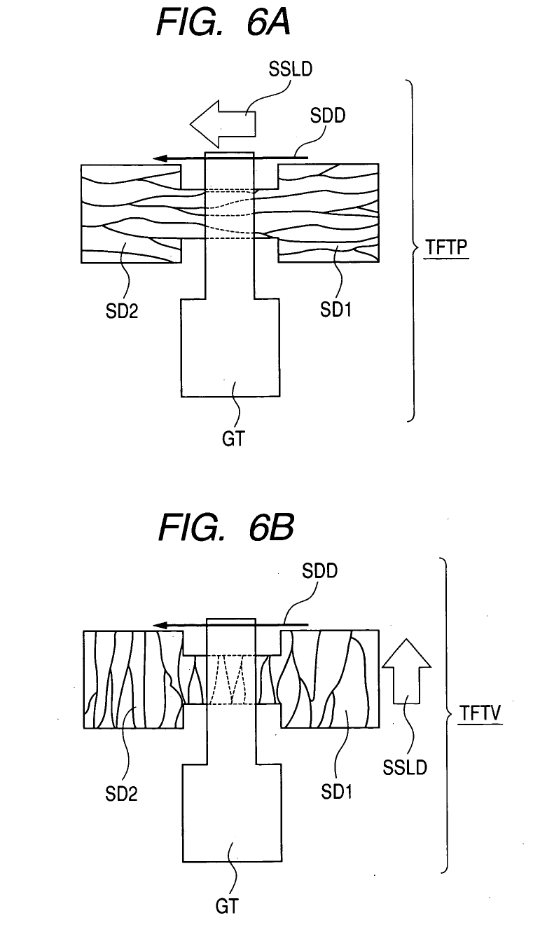

FIGS. 6A and 6B are diagrams illustrating an arrangement of a thin film transistor TFT. As illustrated in FIGS. 6A and 6B, each crystal of the high quality polycrystalline silicon film, namely of the reformed polycrystalline silicon film, is formed in the shape of a belt and is also illustrated as having the crystal grains at the locations of the source electrode SD1, drain electrode DS2, and gate electrode GT. The crystal grain among the silicon crystals exists along the scanning direction of the laser. In FIG. 6A, the thin film transistor is illustrated in the layout such that the scanning direction SSLD of laser becomes parallel to the source, drain direction SDD of the thin film transistor TFTP, while in FIG. 6B, the thin film transistor is illustrated in the layout such that the scanning direction SSLD of laser beam becomes vertical (or crosses) relative to the source, drain direction SDD of the thin film transistor TFTV.

When the thin film transistor formed in the PSI of FIG. 1 is allocated as illustrated in FIG. 6A, the electron mobility becomes as high as 500 cm²/V s from 300 cm²/V s, and the fluctuation in the threshold value becomes ±0.2V or less, because the number of times of scattering of the electrons at the crystal grain interface becomes small.

Moreover, when the thin film transistor formed in the PSI of FIG. 1 is allocated as illustrated in FIG. 6B, the electron mobility of the relevant thin film transistor becomes as low as 300 cm²/V s from 100 cm²/V s, but since the resistance becomes larger, the current becomes small in the off state, the deterioration of the characteristic is lowered, and the transistor characteristic shows a higher dielectric strength. Therefore, for example, the relevant thin film transistor may be used as an element for holding or discharging charges, such as a memory switch.

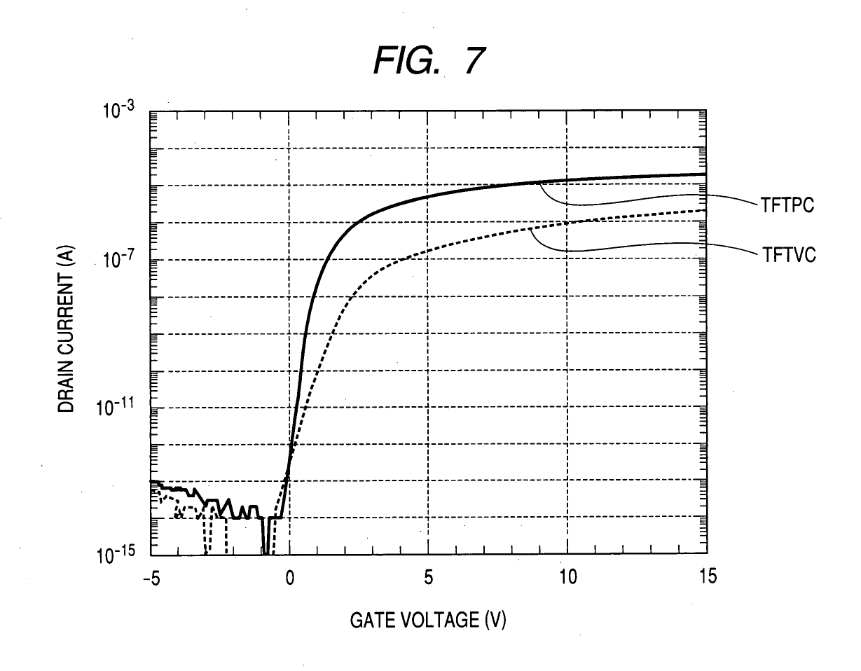

FIG. 7 is a diagram which shows a comparison between the transfer characteristics depending on a difference in the layout of the thin film transistor. The curves TFTPC and TFTVC in FIG. 7 respectively show the transfer characteristics of the thin film transistor of FIG. 6A and the thin film transistor of FIG. 6B. The change in the drain current (μA) when the transfer characteristic is changed, namely, when the gate voltage (V) of the thin film transistor TFTP of FIG. 6A is changed, is larger than that of the thin film transistor TFTV of FIG. 6B.

Fourth Embodiment

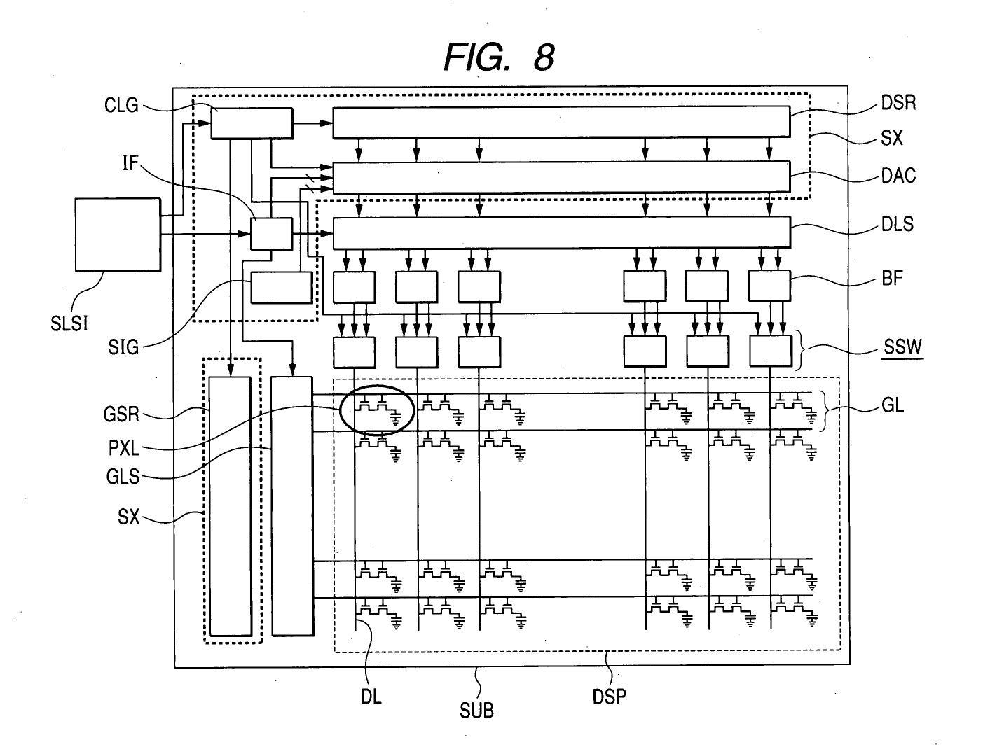

FIG. 8 is a circuit diagram of an image display apparatus representing a fourth embodiment of the present invention, in which a circuit of the display apparatus formed on a glass substrate SUB1 is schematically illustrated. The substrate which forms the glass substrate SUB1 is called an active matrix substrate or a thin film transistor substrate (TFT substrate). Here, an example of the active matrix substrate for a liquid crystal display device of the line sequential system type will be explained. The circuit formed on the glass substrate SUB1 has a pixel region (image display region) DSP in the greater part thereof.

The pixels (pixel circuit) PXL, which are arranged like a matrix in the pixel region DSP, are provided at the intersecting points of the data line DL and gate line GL. The pixel PXL is formed of a thin film transistor TFT operating as a switch and a pixel electrode. In this third embodiment, a double-gate in which a switch is formed of two thin film transistors TFT is illustrated, but a single gate is formed of one thin film transistor TFT, while a multigate is formed of three or more thin film transistors TFT. A drive circuit region forming a circuit to supply the drive signal to many pixels PXL formed in the pixel region DSP is arranged on the external side of the pixel region DSP on the active matrix substrate SUB1.

On one longer side (upper side in FIG. 8) of the pixel region DSP, there are a shift register DSR which serves to control a digital analog converter DAC to sequentially read the digital display data, the digital analog converter DAC for outputting the digital display data as a gradation voltage signal, a level shifter DLS for obtaining the desired gradation voltage by amplifying the gradation signal from the digital analog converter DAC, a buffer circuit BF, and a sampling switch SSW for inverting the polarity of the gradation voltage in the neighboring pixels.

On a shorter side (left side in FIG. 8) of the pixel region DSP, there are a shift register GSR for sequentially opening the gate of the thin film transistor TFT forming a pixel electrode PXL and a level shifter GLS.

Moreover, in the periphery of the above-described circuits, they are an interface IF to fetch the image data sent from a signal source (system LSI) SLSI to a display for signal conversion, a gradation signal generator SIG, and a clock signal generator CLG which operates to generate the clock signal for timing control of each circuit.

The circuits, such as the interface IF, the clock signal generator CLG, the shift register DSR in the drain side, the shift register GSR in the gate side, and the digital analog converter DAC of these circuit groups are designed to realize high speed operation for processing of a digital signal and a low voltage drive for low power consumption. Meanwhile, the pixel PXL is a circuit used to apply a voltage to the liquid crystal to modulate the transmissivity of the liquid crystal, and high voltage drive is inevitably executed to attain gradation. On the other hand, in order to hold the voltage for a constant period, the switching transistor is required to have a low leakage current characteristic. The level shifter DLS in the drain side, the level shifter GLS in the gate side, the buffer circuit BF, and the sampling switch SSW provided between the low voltage drive circuit group and the high voltage drive circuit group are required to produce a high voltage drive in order to send a high voltage analog signal to the pixels.

With a view toward forming a circuit for image display on the active matrix substrate, as explained above, a plurality of thin film transistors TFT having opposite specifications must be mounted simultaneously. For this purpose, the high quality polycrystalline silicon film is employed in a part of the interface IF, the clock signal generator CLG, the shift register DSR in the drain side, the shift register GSR in the gate side, and the digital analog converter DAC. The scope in which the high quality polycrystalline silicon film is employed is indicated with the reference designation SX.

With the thin film transistor group explained above, the high speed circuit group, which has been mounted as an LSI chip on the external side of the image region DSP formed on the glass substrate forming the active matrix substrate, can in turn be formed directly on the same glass substrate SUB1. Accordingly, a reduction of the LSI chip cost and a reduction of the non-pixel region in the periphery of the panel, namely an expansion of the pixel region, may be realized. Moreover, customization of the circuit which has been provided in the steps of LSI chip design and manufacture may be realized in the step of manufacture of the panel. The thin film transistors may also be adapted to the semiconductor circuit LSI chip of the present invention, and this chip can also be mounted into the peripheral circuits of the panel, as in the case of the related art.

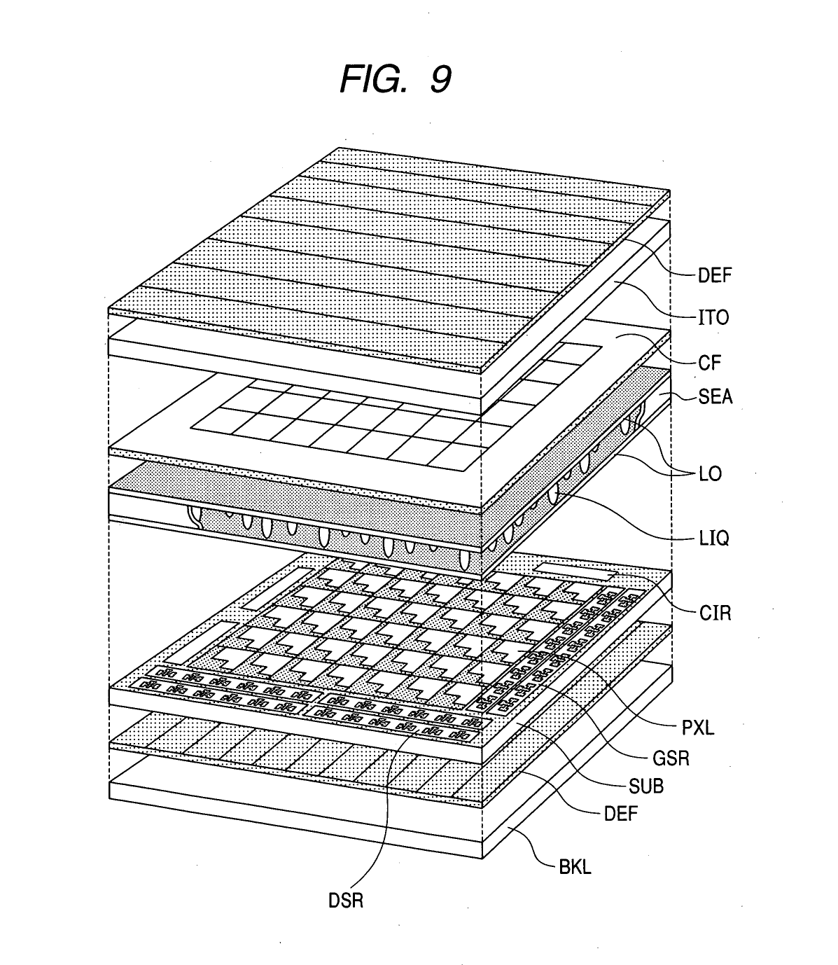

FIG. 9 is a diagram showing an example of a structure in which the thin film semiconductor circuit of the present invention is adapted to a liquid crystal apparatus. A plurality of pixel electrodes PXL arranged in the form of a matrix, the circuits DSR and GSR for inputting the display signal to the pixel electrodes, and the other peripheral circuit group CIR required for image display are formed on the glass substrate SUB1, and an orientation film ORII is coated by use of a printing method to form the active matrix substrate.

On the other hand, a color filter substrate, which has been formed by coating the opposing electrode ITO, color filter CF, and orientation film ORI2 on the glass substrate SUB2, is prepared, and this substrate is then bonded with the active matrix substrate. In the space between the orientation films ORI1 and ORI2 that are opposed to each other, liquid crystal LC is supplied using the vacuum implantation method, and the space is then sealed with a sealing agent SL. Thereafter, a polarization plate DEF is respectively adhered to the external surfaces of the glass substrate SUB1 and glass substrate SUB2. A backlight BKL is also arranged at the rear surface of the active matrix substrate to complete a liquid crystal display apparatus.

Here, a liquid crystal display apparatus has been considered as an example, in which a color filter is formed on the side of the substrate opposing the active matrix substrate. However, the present invention can also be adapted to a liquid crystal display apparatus in which the color filter is formed in on side of the active matrix substrate. Moreover, FIG. 8 illustrates a color filter substrate in which the opposing electrode ITO, color filter CF, and orientation film ORI2 are formed on the glass substrate SUB2 in this sequence. However, it is also possible to form a color filter substrate having a structure such that the color filter CF is formed on the glass substrate SUB2, the opposing electrode ITO is formed on the color filter CF, and the orientation film ORI2 is formed as the upper most layer. The location of the color filter and the structure of the color filter substrate are not directly related to the concept of the present invention.

According to this embodiment, the pixels, the drive circuit for driving these pixels, and the other peripheral circuits can be formed directly on the active matrix substrate in accordance with the requested characteristics. Moreover, a high display quality liquid crystal display apparatus ensuring high speed operation and high resolution can also be achieved.

[Fifth Embodiment]

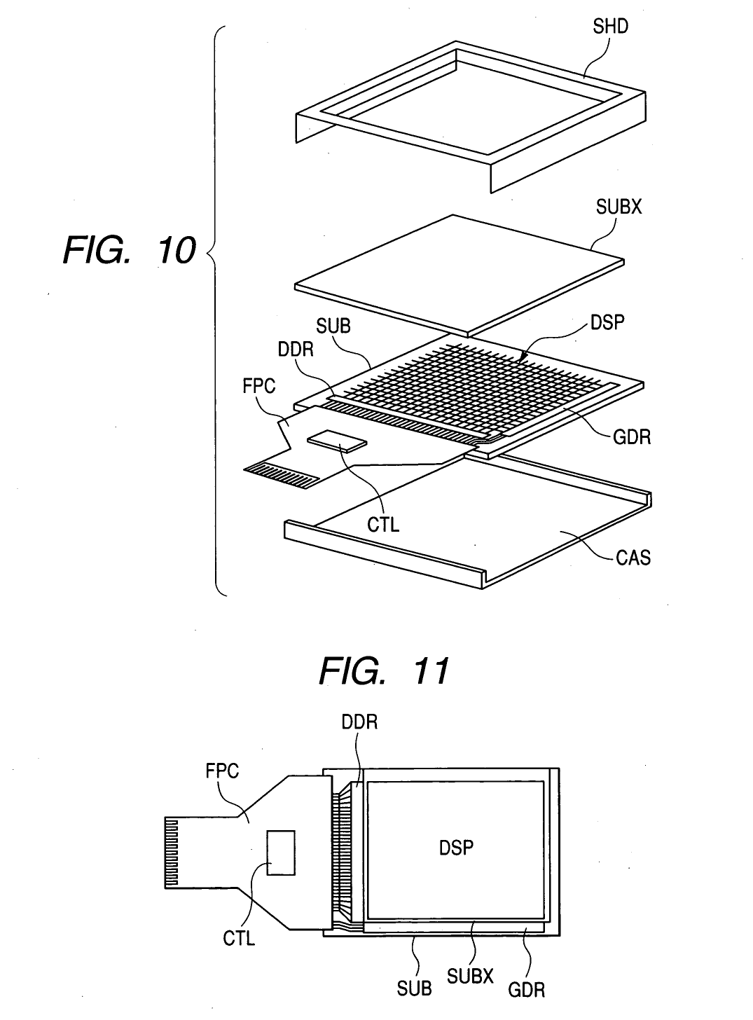

An organic EL display apparatus may also be manufactured using the active matrix substrate of the present invention. FIG. 10 is a perspective view showing an example of the structure of an organic EL display apparatus representing another example of the image display apparatus of the present invention. Moreover, FIG. 11 is a plan view of the organic EL display apparatus integrating the structural elements of FIG. 10. An organic EL element is formed on a pixel electrode which is driven with a thin film transistor provided on the glass substrate SUB, similar to the active matrix substrate in a liquid crystal display apparatus. The organic EL element is constituted with a laminated body which is formed by sequentially evaporating a hole transfer layer, a light emitting layer, an electron transfer layer, and a cathode metal layer from the surface of the pixel electrode. The circumference of the pixel region DSP of the active matrix substrate having such a laminated body is provided with a sealing material, and this active matrix substrate is sealed with a sealing substrate SUBX or a sealing can.

This organic EL display apparatus supplies the display signal sent from an external signal source to the data drive circuit region DDR and gate drive circuit region GDR using a flexible printed circuit board FPC. The peripheral circuits (display control circuit/power source circuit LSI) which cannot be mounted to the DDR, GDR are mounted to the flexible printed circuit board FPC. However, it is also possible to form the circuits corresponding to these LSIs on the glass substrate SUB. The organic EL display apparatus is formed by integrating a shield frame SHD as an upper case and a lower case CAS.

Since the organic EL element is based on a current drive light emitting system in the active matrix drive for the organic EL display apparatus, employment of a high performance pixel circuit is essential to provide a display having a high image quality. Accordingly, it is desirable to use a pixel circuit consisting of a CMOS type thin film transistor. Moreover, the thin film transistor circuit formed in the drive circuit region DDR is also essential to realize a high speed and high resolution image display. The active matrix substrate SUB of this embodiment has a higher performance to satisfy such a requirement. The organic EL display apparatus utilizing the active matrix substrate of the present invention is one of the display apparatuses which exhibits the maximum characteristics of this embodiment.

The pixels, the drive circuit for driving these pixels, and the other peripheral circuits can also be formed directly on the active matrix substrate in accordance with these requested characteristics even with this embodiment. Accordingly, a high display quality organic EL display apparatus, including an expanded pixel region and ensuring high speed operation and a high resolution display of an image, can be obtained.

The present invention is never limited only to the active matrix substrate of the image display apparatus explained above and can also be adapted to various semiconductor devices. Moreover, the present invention is never limited only to the structure described in of claims and the structure described in the description relating to the embodiments and various changes or modifications can be effected without departure from the scope of technical philosophy of the present invention.

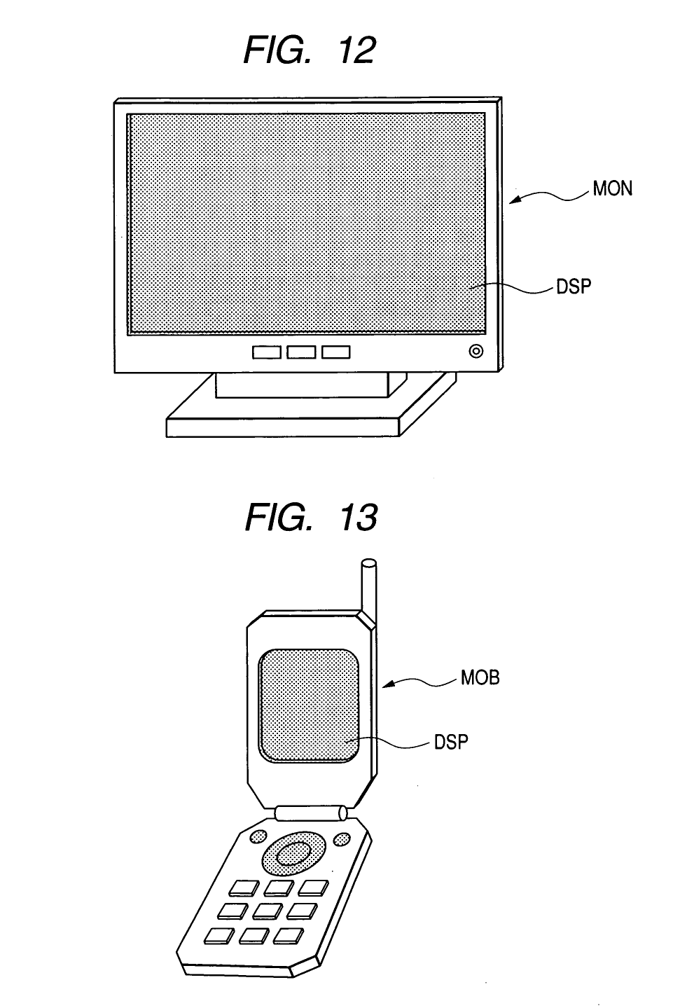

FIG. 12 to FIG. 15 illustrate examples of a liquid crystal image display apparatus in accordance with the present invention. FIG. 12 is a diagram showing an example of the image display apparatus of the present invention as applied to an image display unit DSP of a monitor MON, which may be used as a personal computer and a TV receiver.

FIG. 13 is a diagram showing an example of the image display apparatus of the present invention as applied to the image display unit DSP of a mobile phone MOB.

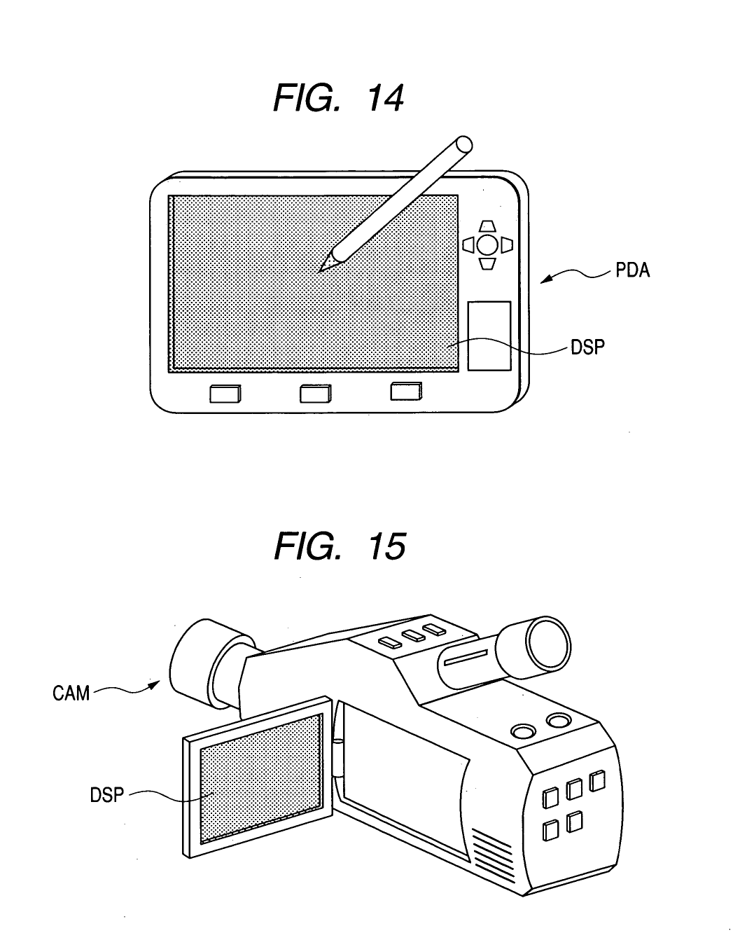

FIG. 14 is a diagram showing an example of the image display apparatus of the present invention as applied to the image display unit DSP of a personal digital assistant PDA.

FIG. 15 is a diagram showing an example of the image display apparatus of the present invention as applied to the image display unit DSP (view finder unit) of a video camera CAM.

Moreover, the liquid crystal display apparatus of the present invention can also be employed for the image display unit of a digital still camera, a projector, a mobile navigation system or the like.

For improvement in the image quality of a display apparatus which is driven by a TFT, it is essential to obtain an improvement in the TFT performance. For this purpose, the crystal property must be improved through elimination of agglomeration of polycrystalline silicon used as the active layer in the process of melting and re-crystallization. Accordingly, the present invention can be adapted to a wide range of devices and products in the semiconductor field and is not limited to the related techniques of an image display apparatus.

1. A thin film semiconductor device using, as an active layer, a semiconductor thin film which is constituted with an insulating substrate and a polycrystalline silicon formed on a layer or a plurality of layers of underlayer, wherein the underlayer near the surface in the side of said semiconductor thin film of said underlayer is constituted with a silicon oxide film and an element having electronegativity which is smaller than that of oxygen is substituted for a plurality of sites among the sites of oxygen in said silicon oxide film.

2. The thin film semiconductor device according to claim 1, wherein said element having electronegativity which is smaller than that of oxygen is nitrogen and concentration of said nitrogen averaged in said silicon oxide film is equal to 2% or higher in the chemical composition ratio.

3. The thin film semiconductor device according to claim 1, wherein said underlayer near the surface in the side of said semiconductor thin film of said underlayer is formed of a material having polarizability which is smaller than that of said silicon oxide film.

4. The thin film semiconductor circuit according to claim 3, wherein said material having polarizability which is smaller than that of said silicon oxide film is diamond-like carbon or silicon carbide and resistivity thereof is equal to 10⁷Ω·cm or larger.

5. A thin film semiconductor circuit using, as an active layer, a semiconductor thin film which is formed of an insulating substrate and a polycrystalline silicon formed on a layer or a plurality of layers of underlayer, wherein said underlayer near the surface in the side of said semiconductor thin film is formed of a silicon oxide film and oxygen concentration averaged in said silicon oxide film is equal to 60% or less in the chemical composition ratio and said semiconductor thin film formed of said polycrystalline silicon includes oxygen atom.

6. The thin film semiconductor device according to claim 5, wherein oxygen concentration of said underlayer is reduced as it becomes closer to the interface with the semiconductor thin film formed of said polycrystalline silicon and oxygen concentration of said semiconductor thin film formed of said polycrystalline silicon increases as it becomes closer to the interface with said under layer.

7. The thin film semiconductor circuit according to claim 1 or 5, wherein said insulating substrate formed of a glass material.

8. The thin film semiconductor device according to claim 1 or 5, wherein the semiconductor thin film formed of said polycrystalline silicon has a peak-to-valley difference of 5 nm or less and the crystal grain of the relevant polycrystalline silicon is formed in the longer rectangular shape in the width of 0.3 μm or more but 2 μm or less and in the length of 4 μm or more.

9. The thin film semiconductor device according to claim 1 or 5, wherein the semiconductor thin film formed of said polycrystalline silicon is formed of the crystal grain having the rectangular or circular shape in the width and length of 1 μm or more.

10. A method of manufacturing thin film semiconductor circuit including a thin film transistor which is formed on an insulating substrate and a layer or a plurality of layers of underlayer and uses a semiconductor thin film formed of polycrystalline silicon as an active layer, comprising the steps of:
forming an insulating film for undercoat on said glass substrate;
forming a precursory silicon film on the upper part of said insulating film;
forming high quality polycrystalline silicon film having the flat surface in which large crystal grain size and grain width are aligned in the scanning direction of laser through radiation of the CW laser to said precursory silicon film; and
forming a thin film transistor using said high quality polycrystalline silicon film as an active layer.

11. The method of manufacturing thin film semiconductor circuit according to claim 10, wherein said CW laser beam is radiated to said precursory silicon film after conversion into the pulse operation with a precisely controlled pulse duration.

12. The method of manufacturing thin film semiconductor circuit according to claim 10, wherein said precursory silicon film is an amorphous silicon film formed with the CVD method.

13-16. (canceled)

17. The image display apparatus according to claim 3, wherein the material having polarizability which is smaller than that of said silicon oxide film is diamond-like carbon or silicon carbide and resistivity thereof is equal to 10⁷Ω·cm or more.

18. An image display apparatus comprising an active matrix substrate in which thin film transistors of each pixel forming the image display region are formed on the semiconductor layer formed on the insulating substrate and the thin film semiconductor devices are formed in the external side of said image display region to form a drive circuit to drive said pixels and a peripheral circuit, wherein said thin film semiconductor circuit includes a semiconductor thin film, as the active layer, which is formed of the polycrystalline silicon formed on a layer or a plurality layers of the underlayer formed on said insulating substrate, the underlayer near the surface in the side of said semiconductor thin film of said underlayer is formed of a silicon oxide film, oxygen concentration averaged in said silicon oxide film is equal to 60% or less in the chemical composition ratio, and the semiconductor thin film formed of said polycrystalline silicon includes oxygen atom.

19. The image display apparatus according to claim 18 wherein oxygen concentration of said underlayer is decreased as it becomes closer to the interface with semiconductor thin film formed of said polycrystalline silicon and oxygen concentration of semiconductor thin film formed of said polycrystalline silicon increases as it becomes closer to the interface with said underlayer.

20. The image display apparatus according to claim 18, wherein said insulating substrate is formed of a glass material.

21. The thin film semiconductor device according to claim 18, wherein the semiconductor thin film formed of said polycrystalline silicon has a peak-to-valley difference of 5 nm or less and the crystal grain of the relevant polycrystalline silicon is formed in the longer rectangular shape in the width of 0.3 μm or more but 2 μm or less and in the length of 4 μm or more.

22. The image display apparatus according to claim 18, wherein the semiconductor thin film formed of said polycrystalline silicon is formed of the crystal grain having the rectangular or circular shape in the width and length of 1 μm or more.
